(19) United States
(12) Patent Application Publication
(10) Pub. No.: US 2013/0300486 A1
(43) Pub. Date: Nov. 14, 2013

(54) REDUCED DELAY LEVEL SHIFTER

(71) Applicant: Conexant Systems, Inc., Irvine, CA (US)

(72) Inventor: Ravindra Kumar, Hyderabad (IN)

(73) Assignee: Conexant Systems, Inc., Irvine, CA (US)

(21) Appl. No.: 13/892,064

(22) Filed: May 10, 2013

Related U.S. Application Data
(60) Provisional application No. 61/646,171, filed on May 11, 2012.

(51) Int. Cl. H03F 3/345

(52) U.S. Cl. CPC H03F 3/345
USPC 327/333

(57) ABSTRACT

A circuit comprising a first input transistor having a drain, a source and a gate. A first diode connected transistor having a drain, a source and a gate, wherein the gate of the first diode connected transistor is coupled to the drain of the first diode connected transistor, and the drain of the first input transistor is coupled to the drain of the first diode connected transistor. A first load transistor having a drain, a source and a gate, wherein the drain of the first load transistor is coupled to the drain of the first diode connected transistor and the source of the first load transistor is coupled to the source of the first diode connected transistor.

### RELATED APPLICATIONS

The present application claims benefit of U.S. provisional patent application 61/646,171, filed May 11, 2012, which is hereby incorporated by reference as if set forth herein in its entirety.

### TECHNICAL FIELD

The present disclosure relates generally to level shifters, and more specifically to a reduced delay level shifter.

### BACKGROUND OF THE INVENTION

In general purpose and specialty input/output (I/O) devices, level-shifting is needed to shift an input signal at a lower amplitude (core voltage of the chip) to higher amplitude and vice versa. The delay of a level up-shifter increases drastically as the core voltage is brought down, I/O voltage is increased and the level-shifter fails to switch below a particular core voltage. This increase in delay is owing to high threshold voltage of the thick-oxide transistor, which is close to the core voltage and the contention between input NMOS and load PMOS devices.

### SUMMARY OF THE INVENTION

A circuit comprising a first input transistor having a drain, a source and a gate. A first diode connected transistor having a drain, a source and a gate, wherein the gate of the first diode connected transistor is coupled to the drain of the first diode connected transistor, and the drain of the first input transistor is coupled to the drain of the first diode connected transistor. A first load transistor having a drain, a source and a gate, wherein the drain of the first load transistor is coupled to the drain of the first diode connected transistor and the source of the first load transistor is coupled to the source of the first diode connected transistor.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE SEVERAL VIEWS OF THE DRAWINGS

Aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views, and in which:

FIG. 1 is a diagram of a level up-shifter in accordance with an exemplary embodiment of the present disclosure;

FIG. 2 is a diagram of a level up-shifter in accordance with an exemplary embodiment of the present disclosure;

FIG. 3 is a diagram showing normalized level-shifter delay (Y-axis) versus core V_{DD} (x-axis) in accordance with an exemplary embodiment of the present disclosure; and

FIG. 4 is a diagram showing core circuitry with reduced delay level shifters that interface with input-output devices, in accordance with an exemplary embodiment of the present disclosure.

### DETAILED DESCRIPTION OF THE INVENTION

In the description that follows, like parts are marked throughout the specification and drawings with the same reference numerals. The drawing figures might not be to scale and certain components can be shown in generalized or schematic form and identified by commercial designations in the interest of clarity and conciseness.

In order to reduce delay, diode-connected transistors can be added in parallel to cross-coupled load-devices that are already present in an I/O device. The diode-connected transistors increase the gain of a positive-feedback loop and enable the circuit to level shift from relatively lower core supply voltages to I/O voltages.

Level up-shifters without native MOSFET suffer from contention between input and load devices and larger delays. Native MOS occupies a relatively large amount of area and will result in increase of I/O device area or “foot-print,” especially when multiple level-shifters are present in a single I/O device. The present disclosure provides an I/O device that occupies a much smaller area and requires a minimal layout change when compared to native MOSFET solutions.

In general purpose and specialty I/O devices, level-shifting is needed to shift an input signal at a lower amplitude (such as the core voltage of the chip) to a higher amplitude, and from the higher amplitude back to the lower amplitude. In a particular digital I/O device, depending on the application, multiple level-shifters can be present. The level shifters in the digital I/O devices should not consume static current and should occupy the smallest possible area. In addition, the delay of a level up-shifter increases as the core voltage is reduced and the I/O device voltage is increased. The level-shifter will fail to switch below a particular core voltage, due to the high threshold voltage of thick oxide transistors used in high voltage I/O devices (˜1V in slow process and low temperature corner, for example, −40 degrees centigrade) and the contention between input NMOS and load PMOS devices. The present disclosure improves the performance of level-shifter delay as core voltage is reduced, without requiring a significant increase in area.

Native MOSFET can be used to bring down the delay of the level up-shifter in CMOS processes that support the device, which reduces the contention of the circuit that can lead to higher delays. This exemplary embodiment provides an optimal delay and can be operated at lower core voltages (e.g. V_{DD}) . In contrast, native MOS occupies more area (minimum length of the device is 1.2 um) and can result in an increase of I/O device area, especially when multiple level-shifters are present in an I/O device.

While high-speed level-shifters that consume static current can be used, they are only suitable for high performance applications where static power is not an issue.

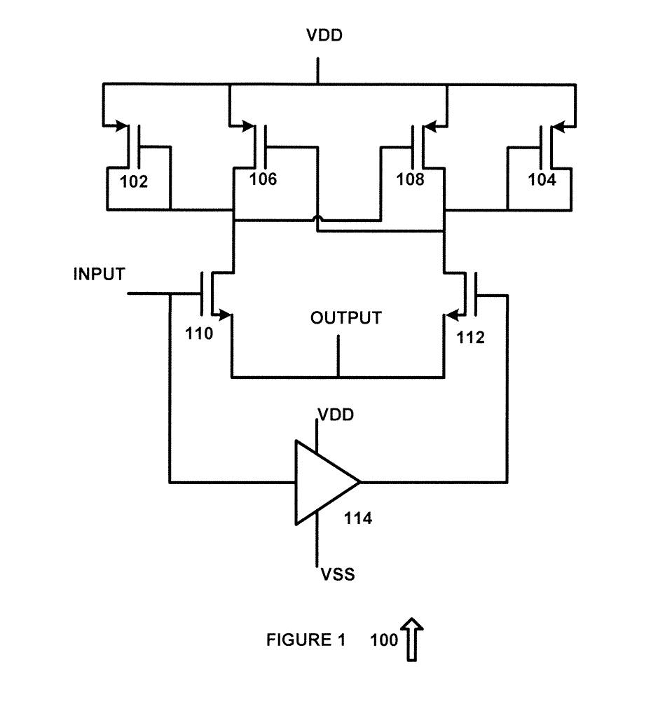

FIG. 1 is a diagram of a level up-shifter 100 in accordance with an exemplary embodiment of the present disclosure. The drain and source of diode-connected PMOS transistors 102 and 104 are coupled to the drain and source of PMOS load transistors 106 and 108, respectively, and are used to compensate for a high threshold of the input NMOS transistors 110 and 112, as well as the contention between input NMOS transistors 110 and 112 and PMOS load transistors 106 and 108, which can result in a higher delay at lower core V_{DD}. Diode-connected PMOS transistors 102 and 104 are added in parallel to the cross-coupled PMOS load transistors 106 and 108, to increase the gain of the positive-feedback loop and enable the circuit to level shift from relatively lower core supply voltages to I/O voltages. The gates of NMOS transistors 110 and 112 are coupled by inverter 114.

The disclosed embodiments occupy less area and require a minimal layout change as compared to a native MOSFET solution, and can be used in applications where there is a need to operate at lower core V_{DD} and where it is not possible to increase the height of the I/O cell to accommodate a native MOS level shifter.

Adding diode-connected transistors in parallel to the load devices will help in level up-shifting from relatively lower core V_{DD} to IO supply voltage, and will help in reduction of the level up-shifter delay.

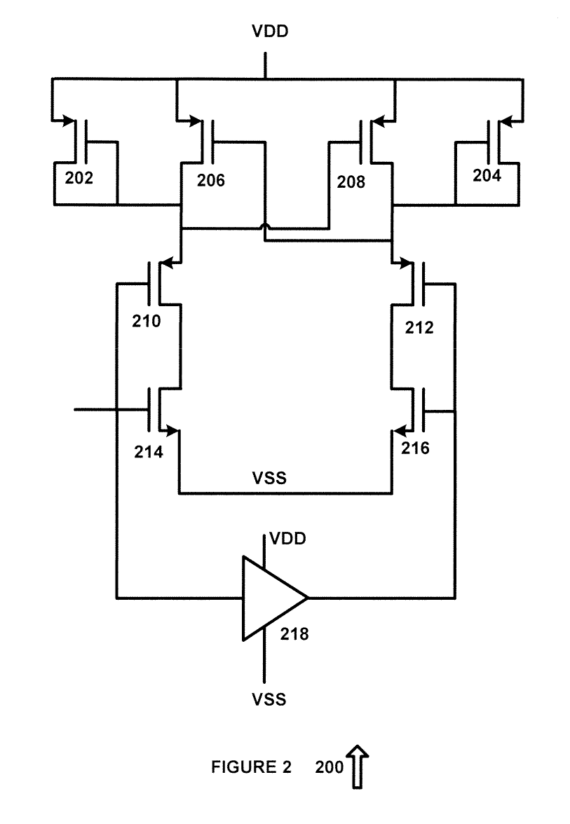

FIG. 2 is a diagram of a level up-shifter 200 in accordance with an exemplary embodiment of the present disclosure. Level up-shifter 200 includes diode-connected PMOS transistors 202 and 204, which are connected in parallel with cross-coupled PMOS load transistors 206 and 208. The source of PMOS transistor 210 is coupled to the drain of PMOS transistor 202 and the gate of PMOS transistor 204. The drain of PMOS transistor 210 is coupled to the drain of NMOS transistor 214. The source of PMOS transistor 212 is coupled to the drain of PMOS transistor 204 and the gate of PMOS transistor 202. The drain of PMOS transistor 212 is coupled to the drain of NMOS transistor 216. The gates of PMOS transistors 210 and 212 and NMOS transistors 214 and 216 are coupled by inverter 218.

As used herein, “hardware” can include a combination of discrete components, an integrated circuit, an application-specific integrated circuit, a field programmable gate array, or other suitable hardware. As used herein, “software” can include one or more objects, agents, threads, lines of code, subroutines, separate software applications, two or more lines of code or other suitable software structures operating in two or more software applications or on two or more processors, or other suitable software structures. In one exemplary embodiment, software can include one or more lines of code or other suitable software structures operating in a general purpose software application, such as an operating system, and one or more lines of code or other suitable software structures operating in a specific purpose software application. As used herein, the term “couple” and its cognate terms, such as “couples” and “coupled,” can include a physical connection (such as a copper conductor), a virtual connection (such as through randomly assigned memory locations of a data memory device), a logical connection (such as through logical gates of a semiconducting device), other suitable connections, or a suitable combination of such connections.

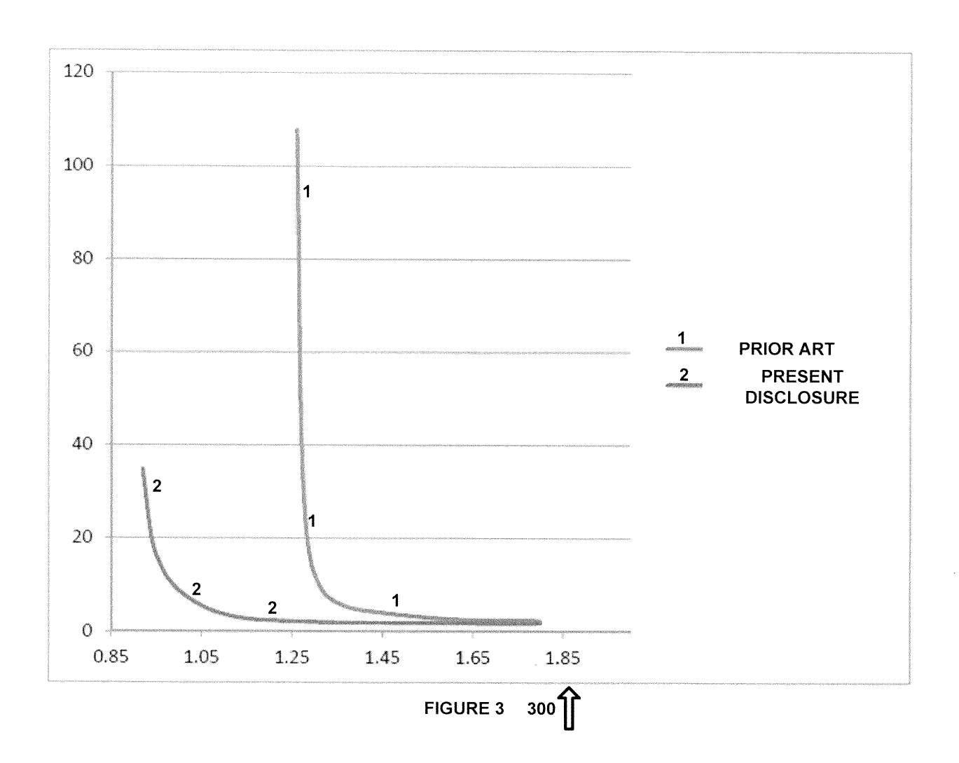

FIG. 3 is a diagram 300 showing normalized level-shifter delay (Y-axis) versus core V_{DD} (x-axis) in accordance with an exemplary embodiment of the present disclosure. In diagram 300, the level up-shifters are simulated to determine the core V_{DD} below which the delay increases and the delays are normalized with the delay of a standard cell buffer. It can be observed that when core V_{DD} is reduced to approximately 1.35V, the normalized delay of the traditional level up-shifter increases. With the proposed solution, the normalized delay increases when core V_{DD} is reduced to 1.04V and below. As such, the core V_{DD} can be decreased to a lower level without any corresponding increase in the normalized delay when using the present disclosure, which improves the performance of level-shifter delay as core voltage is reduced.

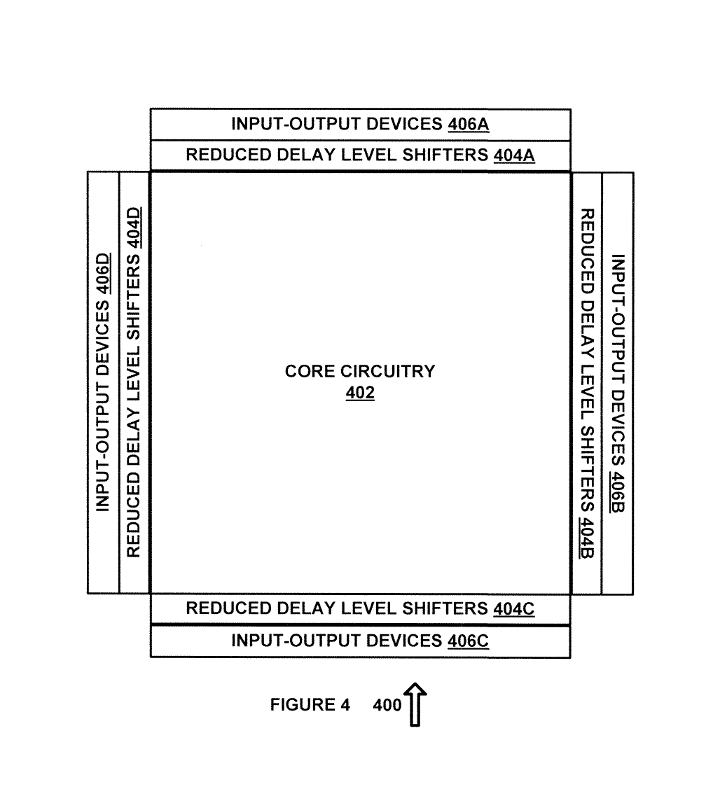

FIG. 4 is a diagram showing core circuitry 402 with reduced delay level shifters 404 that interface with input output devices 406, in accordance with an exemplary embodiment of the present disclosure. In this exemplary embodiment, core circuitry 402 operates at a lower voltage level than would otherwise be possible, because reduced delay level shifters 404A through 404D allow core circuitry 402 to interface with input-output devices 406A through 406D without any corresponding loss in speed of response. Reduced delay level shifters 404A through 404D are disposed between core circuitry 402 and input-output devices 406A through 406D, so as to allow core circuitry 402 to operate at lower voltages without any corresponding delay.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

What is claimed is:

1. A circuit comprising:
a first input transistor having a drain, a source and a gate;
a first diode connected transistor having a drain, a source and a gate, wherein the gate of the first diode connected transistor is coupled to the drain of the first diode connected transistor, and the drain of the first input transistor is coupled to the drain of the first diode connected transistor; and
a first load transistor having a drain, a source and a gate, wherein the drain of the first load transistor is coupled to the drain of the first diode connected transistor and the source of the first load transistor is coupled to the source of the first diode connected transistor.

2. The circuit of claim 1 further comprising a second input transistor having a drain, a source and a gate.

3. The circuit of claim 2 further comprising a second diode connected transistor having a drain, a source and a gate, wherein the gate of the second diode connected transistor is coupled to the drain of the second diode connected transistor, and the drain of the second input transistor is coupled to the drain of the second diode connected transistor.

4. The circuit of claim 3 further comprising a second load transistor having a drain, a source and a gate, wherein the drain of the second load transistor is coupled to the drain of the second diode connected transistor and the source of the second load transistor is coupled to the source of the second diode connected transistor.

5. The circuit of claim 1 further comprising an inverter coupled to the gate of the first input transistor.

6. The circuit of claim 5 wherein the inverter is coupled to V_{DD} and V_{SS} and the source of the first diode connected transistor is coupled to V_{DD}.

7. The circuit of claim 1 wherein the source of the first input transistor is coupled to an output.

8. The circuit of claim 1 further comprising a fourth transistor having a source coupled to the drain of the first load transistor and a drain coupled to the drain of the first input transistor, and wherein the drain of the first input transistor is not coupled to the drain of the first diode connected transistor.

9. A level-shifter circuit comprising:
a first input device having a drain, a source and a gate;
a first diode connected device having a drain, a source and a gate, wherein the gate of the first diode connected device is coupled to the drain of the first diode connected device, and the drain of the first input device is coupled to the drain of the first diode connected device; and
a first load device having a drain, a source and a gate, wherein the drain of the first load device is coupled to the drain of the first diode connected device and the source of the first load device is coupled to the source of the first diode connected device.

10. The circuit of claim 9 further comprising a second input device having a drain, a source and a gate.

11. The circuit of claim 10 further comprising a second diode connected device having a drain, a source and a gate, wherein the gate of the second diode connected device is coupled to the drain of the second diode connected device, and the drain of the second input device is coupled to the drain of the second diode connected device.

12. The circuit of claim 11 further comprising a second load device having a drain, a source and a gate, wherein the drain of the second load device is coupled to the drain of the second diode connected device and the source of the second load device is coupled to the source of the second diode connected device.

13. The circuit of claim 9 further comprising an inverter coupled to the gate of the first input device.

14. The circuit of claim 13 wherein the inverter is coupled to V_{DD} and V_{SS} and the source of the first diode connected device is coupled to V_{DD}.

15. The circuit of claim 9 wherein the source of the first input device is coupled to an output.

16. The circuit of claim 9 further comprising a fourth device having a source coupled to the drain of the first load device and a drain coupled to the drain of the first input device, and wherein the drain of the first input device is not coupled to the drain of the first diode connected device.

17. A level-shifter circuit comprising:
two cross-coupled load devices; and
two diode-connected devices, each coupled in parallel to one of the two cross-coupled load devices and configured to increase a gain of a positive-feedback loop and to enable the level-shifter circuit to level shift from a lower supply voltage to an input-output voltage.

18. The level-shifter circuit of claim 17 wherein the positive feedback loop is formed by coupling a gate of a first of the two cross-coupled load devices to a drain of a second of the two cross-coupled load devices.

19. The level-shifter circuit of claim 17 wherein the positive feedback loop is formed by coupling a gate of a first of the two cross-coupled load devices to a drain of a second of the two cross-coupled load devices and by coupling a gate of the second of the two cross-coupled load devices to a drain of the first of the two cross-coupled load devices.

20. The level-shifter circuit of claim 17 further comprising a pair of input devices, each coupled to one of the load devices and one of the two cross-coupled load devices and one of the two diode connected devices, and wherein the positive feedback loop is formed by coupling a gate of a first of the two cross-coupled load devices to a drain of a second of the two cross-coupled load devices and by coupling a gate of the second of the two cross-coupled load devices to a drain of the first of the two cross-coupled load devices.
